(19) United States
(12) Patent Application Publication
(10) Pub. No.: US 2005/0052186 A1
(43) Pub. Date: Mar. 10, 2005

(54) Circuit testing device for testing electrical subsystems of vehicles

(76) Inventor: Juan C. Grube, Raymore, MO (US)

Correspondence Address: Hovey Williams LLP;Suite 400, 2405 Grand Blvd., Kansas City, MO, 64108, US

(21) Appl. No.: 10/655,439

(22) Filed: Sep. 4, 2003

(51) Int. Cl. G01R 31/00

(52) U.S. Cl. 324/503

(57) ABSTRACT

A circuit testing device adapted and operable to allow a single technician to properly and practically test an electrical subsystem of a vehicle. More specifically, the device is adapted to substantially automatically perform the particular recommended or required tests for investigating or diagnosing the electrical subsystem, and to straightforwardly communicate the results of those tests as being either satisfactory or unsatisfactory without requiring complex interpretation by the technician. The device broadly comprises a housing, including a display and control panel; one or more connectors; and testing circuitry. The display and control panel uses green LEDs to indicate satisfactory or good results and red LEDs to indicate unsatisfactory or bad results. The testing circuitry also provides for any recommended or required testing procedures such as, for example, delay periods to allow circuits to stabilize, and voltage checks to ensure sufficient voltage for performing the test and achieving an accurate result.

### BACKGROUND OF THE INVENTION

1. Field of the Invention

The present invention relates broadly to diagnostic or test equipment for electrical subsystems of vehicles. More particularly, the present invention relates to a circuit testing device for testing an electric starter, battery charging, or other electrical subsystems of a vehicle, wherein the device includes sufficient connectors or probes and tailored testing circuitry to allow a single technician to perform multiple tests simultaneously, and includes a simple display for communicating the results of those tests as being either satisfactory or unsatisfactory without requiring complex interpretation by the technician.

2. Description of the Prior Art

When diagnosing vehicular problems, it is sometimes desirable or necessary to investigate the vehicle's electrical subsystems, such as, for example, the electric starter subsystem or battery charging subsystem. With regard, for example, to the electric starter subsystem, proper testing of the starter circuit involves verifying voltage before and during cranking (approximately 9.6 Volt); measuring a first voltage drop between the positive battery terminal and the positive starter terminal; measuring a second voltage drop between the negative battery terminal and ground; and measuring a third voltage drop between the ignition switch and solenoid. These measurements should be made substantially simultaneously so as to ensure identical test conditions (e.g., battery charge). Unfortunately, simultaneous measurements may require up to four technicians, one for each test, and a fifth person to engage the ignition and crank the starter depending on the various distances involved and the nature of the test equipment. Unfortunately, it will be appreciated that devoting five people to diagnosing an electrical subsystem is generally not cost-effective or otherwise practical, and therefore the measurements are often not made simultaneously or other compromises occur giving rise to potentially incorrect or unreliable test results.

Furthermore, proper testing requires a delay period following the start of cranking in order to allow the starter circuit to stabilize. This is because a large current will flow initially during cranking, resulting in a large voltage drop. Only after the starter circuit has stabilized can accurate measurements be taken. Unfortunately, technicians are often unaware of, do not remember, or do not wish to be bothered with this requirement. Also, because cranking the starter reduces the battery charge and recharging the battery can take hours, technicians who are aware of the need to stabilize the starter circuit are often reluctant to allow for the proper delay period in order to avoid having to recharge the battery.

Additionally, conventional multimeters or other test equipment typically do not provide sufficient probes or probe connections for conducting multiple tests simultaneously. Even if it were cost-effective and otherwise practical to provide each of the aforementioned technicians with his or her own multimeter so that the tests could be conducted simultaneously, each technician would need to know and remember or be able to calculate the correct reading or range of readings for his or her assigned test because the multimeter provides only a raw reading with no indication as to whether the reading indicates proper operation of the electrical subsystem.

It will also be appreciated that many product warranties are of the repair-or-replace type. Of course, repair can only be accomplished after a proper diagnosis is made. In light of the aforementioned obstacles to properly and practically investigating electrical subsystems, a great deal of unnecessary replacement occurs. This can have a substantial negative impact on the businesses providing the electrical subsystems or components thereof.

Due to the above-identified and other problems and disadvantages in the prior art, a need exists for an improved circuit testing device for properly and practically testing electrical subsystems of vehicles.

### SUMMARY OF THE INVENTION

The present invention overcomes the above-described and other problems and disadvantages in the prior art by providing a circuit testing device broadly adapted and operable to allow a single technician to properly and practically investigate or diagnose an electrical subsystem of a vehicle. More specifically, the device is adapted to substantially automatically perform the multiple recommended or required tests for investigating or diagnosing the electrical subsystem, and for straightforwardly communicating the results of those tests as being either satisfactory or unsatisfactory without requiring complex interpretation by the technician. The device broadly comprises a housing, including a display and control panel; one or more connectors; and testing circuitry.

The housing provides a rugged, preferably ergonomic support structure for the display and control panel and a protective, preferably water resistant enclosure for the testing circuitry.

The display and control panel is adapted and operable to communicate in an easily understandable and straightforward manner results of the tests performed by the testing circuitry. The panel includes multiple pairs of result indicators, which are preferably green and red LEDs; a reset button; and a 24 Volt indicator LED. Each pair of indicator LEDs communicates the result of a different measurement or test performed by the testing circuitry, with the green LED indicating an acceptable result and the red LED indicating an unacceptable result. The red LED may also indicate a loose connector or broken connection, which, it will be appreciated is particularly advantageous given that any number of the various connectors and connections may not be visible to the technician during testing. The reset button allows for resetting or clearing the testing circuitry in order to conduct a second or subsequent test without disconnecting the connectors. More specifically, the testing circuitry latches the results of a test so that the LEDs continue to display the results so long as the connectors are connected, and the reset button allows for clearing the testing circuitry of the previous results so that a new test may be conducted and new results reported without disconnecting and reconnecting the connectors. The 24 Volt indicator LED indicates that the testing circuitry recognizes that it is connected to either a 12 Volt system or 24 Volt system.

The one or more connectors are adapted and operable to mechanically secure to or couple with a component of the electrical subsystem being tested and to electrically connect the component with the testing circuitry. Each connector includes a mechanical or physical coupling and an electrically conductive wire extending therefrom to the testing circuitry. The number of connectors will depend to some extent on the number and nature of the particular electrical subsystem and the tests to be performed. The connectors are preferably distinctly colored or otherwise distinguished so as to facilitate the technician properly identifying and connecting each connector.

The testing circuitry is adapted and operable to substantially automatically perform the various tests needed in order to properly investigate or diagnose the electrical subsystem. Input is received via the connectors, processed by the testing circuitry, and the results output or communicated as either satisfactory or unsatisfactory by the pairs of LEDs of the display and control panel. The testing circuitry preferably provides for any recommended or required test procedures, including pre-test procedures such as, for example, delay periods to allow circuits to stabilize, and voltage checks to ensure sufficient initial voltage for performing the tests and achieving accurate results.

Thus, it will be appreciated that the circuit testing device of the present invention provides a number of substantial advantages over the prior art, including, for example, allowing a single technician to substantially simultaneously perform multiple recommended or required tests for proper investigation and diagnosis of the electrical subsystem. Performing the tests substantially simultaneously means that test conditions (e.g., battery charge) are substantially identical for each test. This is a marked advantage over the prior art wherein either an impractical number of technicians and multimeters might be required for each test or, more likely, the tests are not performed simultaneously or other compromises are made giving rise to potentially incorrect or unreliable results.

Furthermore, the present invention substantially ensures that most or all desirable and necessary pre-test and test procedures (e.g., delay period to allow circuit to stabilize, confirming sufficient initial charge on battery) are followed. This is in contrast to the prior art wherein technician's were required to remember and properly follow all such procedures.

Additionally, the present invention provides a testing mechanism tailored to the requirements for testing the particular electrical subsystem. This includes, for example, providing sufficient probes to perform all tests with a single instance of the device, rather than requiring multiple two-probe multimeters. This also includes communicating the results of the tests in a more useful, user-friendly, and intuitive manner. Mores specifically, because the device is test-specific, results can be reported as satisfactory (green LED or other first indicator) or unsatisfactory (red LED or other second indicator). This is a marked advantage over the prior art wherein the technicians were required to correctly interpret multimeter readings to determine whether results were satisfactory or not.

Thus, because the present invention automates and makes more user-friendly much of the testing required to properly investigate and diagnose the electrical subsystem, technicians are more likely to do so. This, in turn, may result in more equipment or product repairs and fewer replacements and thereby decreases costs to businesses or other warrantors covering the electrical subsystem or components thereof.

These and other important features of the present invention are more fully described in the section titled DETAILED DESCRIPTION OF A PREFERRED EMBODIMENT, below.

### BRIEF DESCRIPTION OF THE DRAWINGS

A preferred embodiment of the present invention is described in detail below with reference to the attached drawing figures, wherein:

FIG. 1 is a depiction of a preferred first embodiment of the circuit testing device of the present invention shown adapted for testing and connected to an exemplary electric starter subsystem;

FIG. 2 is a first portion of a circuit schematic of a testing circuitry component of the device shown in FIG. 1;

FIG. 3 is a second portion of the circuit schematic;

FIG. 4 is a third portion of the circuit schematic; and

FIG. 5 is a circuit schematic and diagram of a preferred second embodiment of the circuit testing device of the present invention shown adapted for testing and connected to an exemplary battery charging subsystem.

### DETAILED DESCRIPTION OF A PREFERRED EMBODIMENT

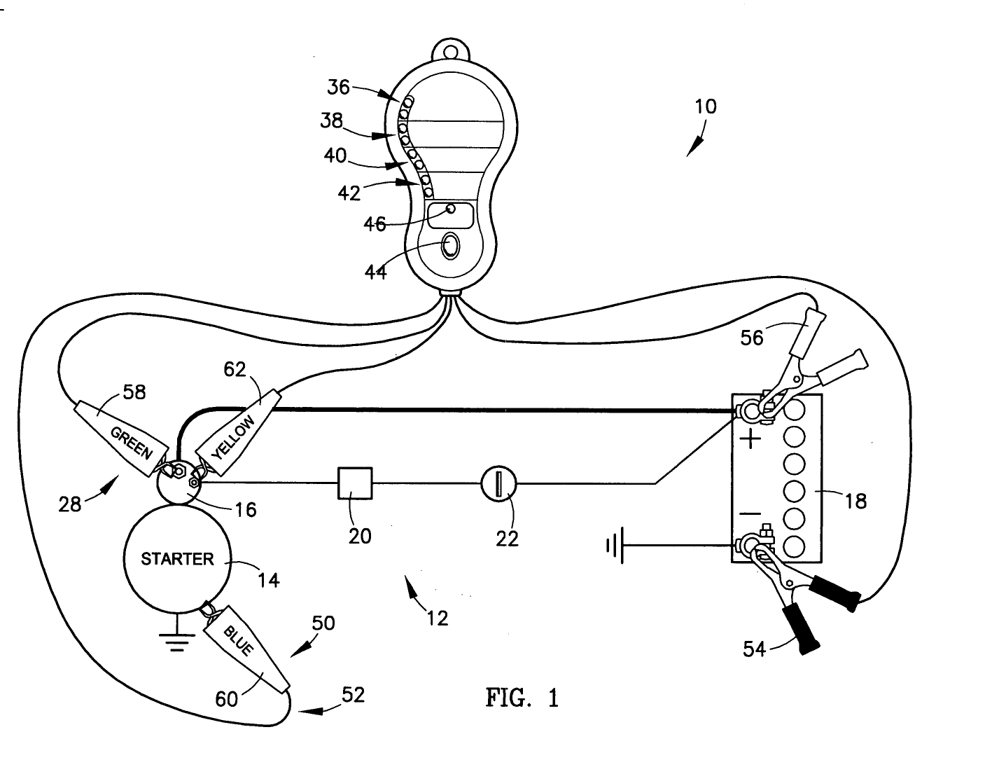

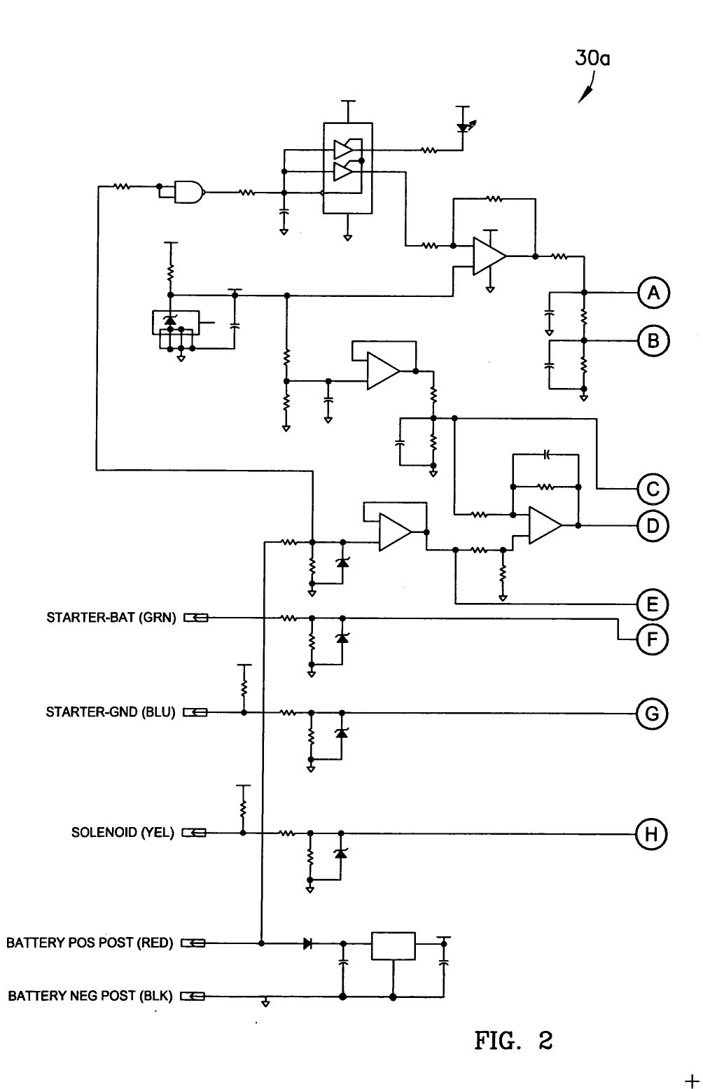

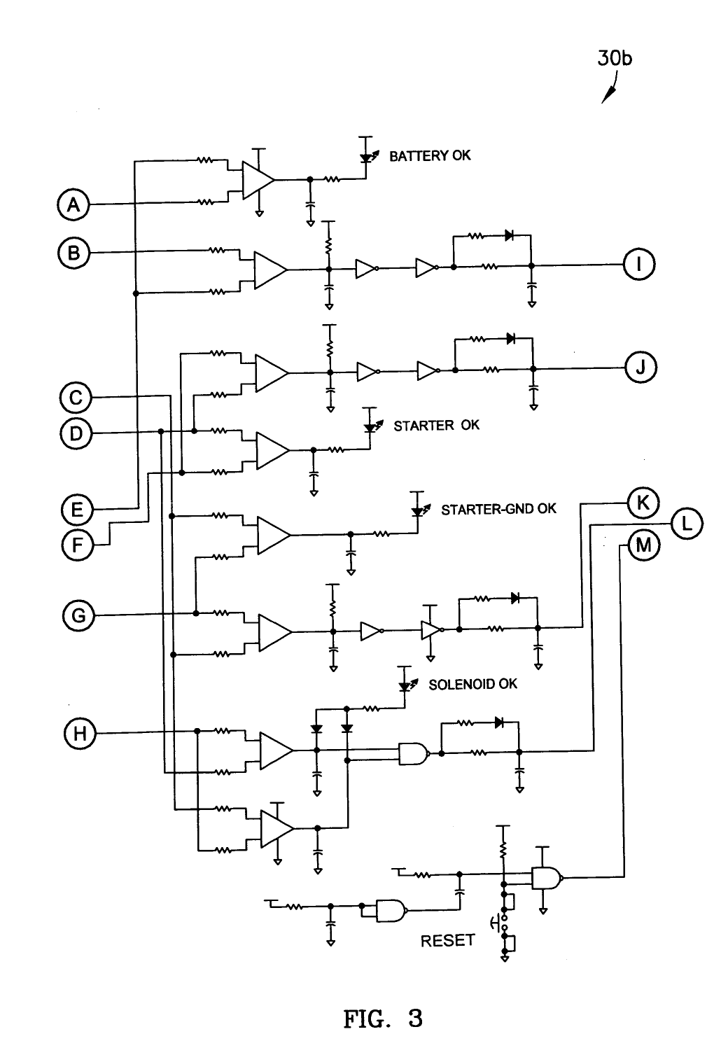

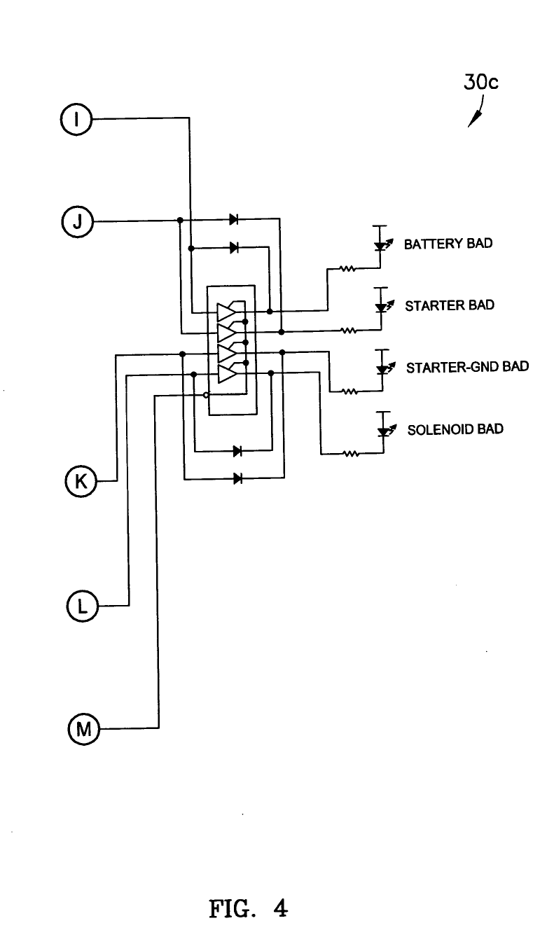

With reference to the figures, a circuit testing device 10 is herein described, shown, and otherwise disclosed in accordance with a preferred first embodiment of the present invention. The device 10 is broadly adapted and operable to allow a single technician to substantially simultaneously perform all recommended or necessary tests for proper investigation and diagnosis of the electrical subsystem. More specifically, the device 10 is adapted to substantially automatically and simultaneously perform multiple tests, and to straightforwardly communicate the results of those tests as being either satisfactory or unsatisfactory without requiring complex interpretation by the technician. An exemplary electric starter subsystem 12, for example, will typically include or make use of a starter 14; a starter solenoid 16; a battery 18; a neutral or clutch safety switch 20; and an ignition switch 22. It will be appreciated, however, that the device 10 may be adapted for testing substantially any electrical subsystem and is not therefore limited to electric starter subsystem 12 shown in FIG. 1. As illustrated, the device 10 broadly comprises a housing 24, including a display and control panel 26; one or more connectors 28; and testing circuitry 30a,30b,30c (FIGS. 2-4).

The housing 24 provides a rugged support structure for the display and control panel 26 and a protective enclosure for the testing circuitry 30a,30b,30c. The housing 24 can be constructed from lightweight high-impact plastic or another similarly suitable material. The housing 24 is preferably substantially sealed, using, e.g., a gasket, rubber seal, or sealing compound, so as to provide a water resistant environment for the testing circuitry 30a,30b,30c. Preferably, the housing 12 is ergonomically designed for easier use, and includes a connection point 34 for receiving a cord or hook for allowing the housing 12 to be securely hung during storage, carrying, or hands-free operation.

The display and control panel 26 is adapted and operable to communicate in a straightforward and easily understandable manner results of measurements made or tests performed by the testing circuitry 30a,30b,30c. The panel 26 broadly includes pairs of result indicators 36,38,40,42, which are preferably green and red LEDs; a reset button 44; and a 24 Volt indicator LED 46. Each pair of indicator LEDs 36,38,40,42 communicates the result of a different test, with the green LED or other first indicator indicating an acceptable result and the red LED or other second indicator indicating an unacceptable result. Additionally, each pair of LEDs 36,38,40,42 is visually associated with one or more of the connectors 28 so that the technician is reminded of or can easily determine the electrical connection to which each LED relates. In a contemplated implementation, each connector 28 is a different color and each pair of LEDs 36,38,40,42 is associated with the color of their corresponding connector 28. Preferably, the display and control panel will include appropriate text to remind the technician of the meanings of the various LEDs. It will be appreciated that rather than using green and red LEDs to communicate the results, other straightforward and easily understood indicators may be used such as, for example, other colors of LEDs, lighted lettering (e.g., “GOOD”, “BAD”), or distinctive sounds.

The red LED or other corresponding indicator also indicates a loose connector 28 or broken connection during testing. This is based on the fact that while a voltage drop of 0 Volts may be theoretically perfect and desirable, it almost never occurs in practice unless a connector 28 has become loose or the connection is otherwise poor or broken. It will be appreciated that this feature is particularly advantageous given that any number of the various connectors 28 and connections may not be visible to the technician during testing.

The reset button 44 allows for resetting the testing circuitry 30a,30b,30c in order to conduct a second or subsequent test without disconnecting the connectors 28. More specifically, the testing circuitry 30a,30b,30c latches the results of a test so that the LEDs 36,38,40,42 continue to display the results so long as the connectors 28 are connected; the reset button 44 allows for clearing the testing circuitry 30a,30b,30c of the latched results of a previous test without removing power from the device 10 by disconnecting the connectors 28.

The 24 Volt indicator LED 46 indicates that the testing circuitry 30a,30b,30c recognizes that it is connected to a 12 Volt system, 24 Volt system, or a system having some other characteristic system voltage. It will be appreciated that such proper recognition of the characteristic system voltage by the testing circuitry 30a,30b,30c is important because the distinction affects the interpretations of the results of the tests performed by the testing circuitry 30a,30b,30c.

The one or more connectors 28 are adapted and operable to mechanically secure to or couple with a component of the electrical subsystem being tested and to electrically connect the component with the testing circuitry 30a,30b,30c of the device 10. Each connector 28 includes a mechanical or physical coupling 50 for securing to a terminal, post, or other component of the electrical subsystem, and an electrically conductive wire 52 extending therefrom to the testing circuitry 30a,30b,30c. As mentioned, the device 10 may be adapted for testing substantially any electrical subsystem. As illustrated, however, being adapted for testing the electric starter subsystem 12, there are five connectors 28. More specifically, there are a black-colored connector 54; a red-colored connector 56; a green-colored connector 58; a blue-colored connector 60; and a yellow-colored connector 62. In use, the black-colored connector 54 is connected to the negative terminal of the battery 18; the red-colored connector 56 is connected to the positive terminal of the battery 18; the green-colored connector 58 is connected to the starter battery terminal in order to test the starter cable extending between the starter battery terminal and the positive battery terminal; the blue-colored connector 60 is connected to ground at the starter housing in order to test the electrical ground at the starter 14 and at the negative battery terminal; the yellow-colored connector 62 is connected to the solenoid ignition terminal in order to test the connections between solenoid 16, the neutral or clutch safety switch 20, the ignition switch 22, and the positive battery terminal.

The testing circuitry 30a,30b,30c is adapted and operable to perform the various recommended or required tests to properly investigate the electrical subsystem. Input is received via the connectors 28, processed by the testing circuitry 30a,30b,30c, and the results output or communicated by the pairs of LEDs 36,38,40,42 of the display and control panel 26. As illustrated, the testing circuitry 30a,30b,30c relies heavily on comparator circuits using operational amplifiers. Preferably, the testing circuitry 30a,30b,30c provides an automatic delay period of approximately one second following instigation of cranking the starter 14 and prior to performing any testing in order to allow the electrical subsystem and the testing circuitry 30a,30b,30c to stabilize. Though design and implementation of the testing circuitry 30a,30b,30c is considered to be within the normal ability of one with ordinary skill in the electrical or electronic arts, an exemplary circuit schematic is shown extending over FIGS. 2, 3, and 4. The present invention is not, however, limited to the particular circuit schematic or the particular electrical or electronic components shown.

It should be noted that the device 10 requires no internal power supply, being instead powered by the vehicle's battery 18 once properly connected.

In exemplary use and operation, the device 10 functions as follows when testing the starter 14 having the solenoid 16 on the starter 14. The device 10 can also be used to test a starter having a separate solenoid. In preparation for testing, the black-colored connector 54 is connected to the negative terminal of the battery 18; the red-colored connector 56 is connected to the positive terminal of the battery 18; the green-colored connector 58 is connected to the starter battery terminal in order to test the starter cable extending between the starter battery terminal and the positive battery terminal; the blue-colored connector 60 is connected to ground at the starter housing in order to test the electrical ground at the starter 14 and at the negative battery terminal; the yellow-colored connector 62 is connected to the solenoid ignition terminal in order to test the connections between solenoid 16, the neutral or clutch safety switch 20, the ignition switch 22, and the positive battery terminal.

Once connected, all of the LEDs of the display and control panel 26 will illuminate for approximately one second in order to confirm their proper operation. The 24 Volt indicator LED 46 communicates which voltage level the testing circuitry 30a,30b,30c has detected and self-calibrated for, whether 12 Volts, 24 Volts, or some other characteristic system voltage. The 24 Volt indicator LED 46 will light, for example, if a 12 Volt system has been detected, and will not light if a 24 Volt system has been detected. Once cranking of the starter 14 occurs, the testing circuit 30a,30b,30c waits for the approximately one second delay to allow for circuit stabilization before any result is given.

The first pair of LEDs 36 communicates the state of the battery 18. Before cranking the starter 14, the green LED will light if the red and black connectors 54,56 are properly connected to the battery terminals and the testing circuitry 30a,30b,30c determines that the battery voltage is 12.4 Volts or more (assuming a characteristic system voltage of 12 Volts). If the green LED is not lit, then the battery voltage is too low for accurate testing and the battery 18 should be charged or replaced before continuing. The red LED will light if the red and black connectors 54,56 are properly connected to the battery terminals and the testing circuitry 30a,30b,30c determines that the battery voltage is 10.0 Volts or less. When cranking the starter 14, the green LED will remain lit so long as the battery voltage remains above 10 Volts, and the red LED will light if the battery voltage falls below 10 Volts.

The second pair of LEDs 38 communicates the state of the electrical connection between the starter battery terminal and the positive battery terminal. Before cranking the starter 14, the green LED will light if the green-colored connector 58 is properly connected to the starter battery terminal and the testing circuitry detects a voltage there at. The red LED will light if the green-colored connector 58 is not properly connected to the starter battery terminal or no voltage is detected. When cranking the starter 14, the green LED will remain lit so long as any detected voltage drop at the starter battery terminal is no greater than approximately 0.7 Volts, and the red LED will light if the detected voltage drop exceeds approximately 0.7 Volts.

The third pair of LEDs 40 communicates the state of the electrical ground at the starter 14. Before cranking the starter 14, the green LED will light if the blue-colored connector 60 is properly connected to the starter housing and the testing circuitry 30a,30b,30c detects an electrical ground. The red LED will light if the blue-colored connector 60 is not properly connected or no electrical ground is detected. When cranking the starter 14, the green LED will remain lit so long as the electrical ground is maintained and any detected voltage drop is within an acceptable range, and the red LED will light if the testing circuitry 30a,30b,30c detects a voltage drop outside of the acceptable range indicating that the electrical ground has not been satisfactorily maintained.

The fourth pair of LEDs 42 communicates the state of the electrical connections between the solenoid 16, the neutral or clutch safety switch 20, the ignition switch 22, and the positive battery terminal. The green LED will light if the yellow-colored connector 62 is properly connected to the solenoid ignition terminal and the testing circuitry 30a,30b,30c determines that the coil within the solenoid 16 is good. The red LED will light if the yellow-colored connector 62 is not properly connected or the coil is bad. When cranking the starter 14, the green LED will remain lit so long as the any detected voltage drop at the solenoid ignition terminal is no greater than approximately 0.7 Volt, and the red LED will light if any detected voltage drop exceeds approximately 0.7 Volt.

If it is desired to retest the electric starter subsystem 12, the reset button 44 is pushed to clear the previous results and allow for displaying the new results.

From the preceding description it will be appreciated that the circuit testing device of the present invention provides a number of substantial advantages over the prior art, including, for example, allowing a single technician to substantially simultaneously perform all recommended or necessary tests for proper investigation and diagnosis of the electrical subsystem. Performing the tests substantially simultaneously means that test conditions (e.g., battery charge) are substantially identical for each test. This is a marked advantage over the prior art wherein either an impractical number of technicians and multimeters might be required for each test or, more likely, the tests are not performed simultaneously or other compromises are made giving rise to potentially incorrect or unreliable results.

Furthermore, the present invention substantially ensures that most or all desirable and necessary test procedures (e.g., delay period to allow circuit to stabilize, confirming sufficient initial charge on battery) are followed. This is in contrast to the prior art wherein technician's were required to remember and properly follow such all procedures.

Additionally, the present invention provides a testing mechanism tailored to the requirements for testing the particular electrical subsystem. This includes, for example, providing sufficient probes to perform all tests with a single instance of the device, rather than requiring multiple two-probe multimeters. This also includes communicating the results of the tests in a more useful, user-friendly, and intuitive manner. Mores specifically, because the device is test-specific, results can be reported as satisfactory or good (green LED or other first indicator) or unsatisfactory or bad (red LED or other second indicator). This is a marked advantage over the prior art wherein the technicians were required to correctly interpret multimeter readings to determine whether results were satisfactory or not.

Thus, because the present invention automates and makes more user-friendly much of the testing required to properly investigate and diagnose the electrical subsystem, technicians are more likely to do so. This, in turn, may result in more equipment or product repairs and fewer replacements and thereby decreases costs to businesses or other warrantors covering the electrical subsystem or components thereof.

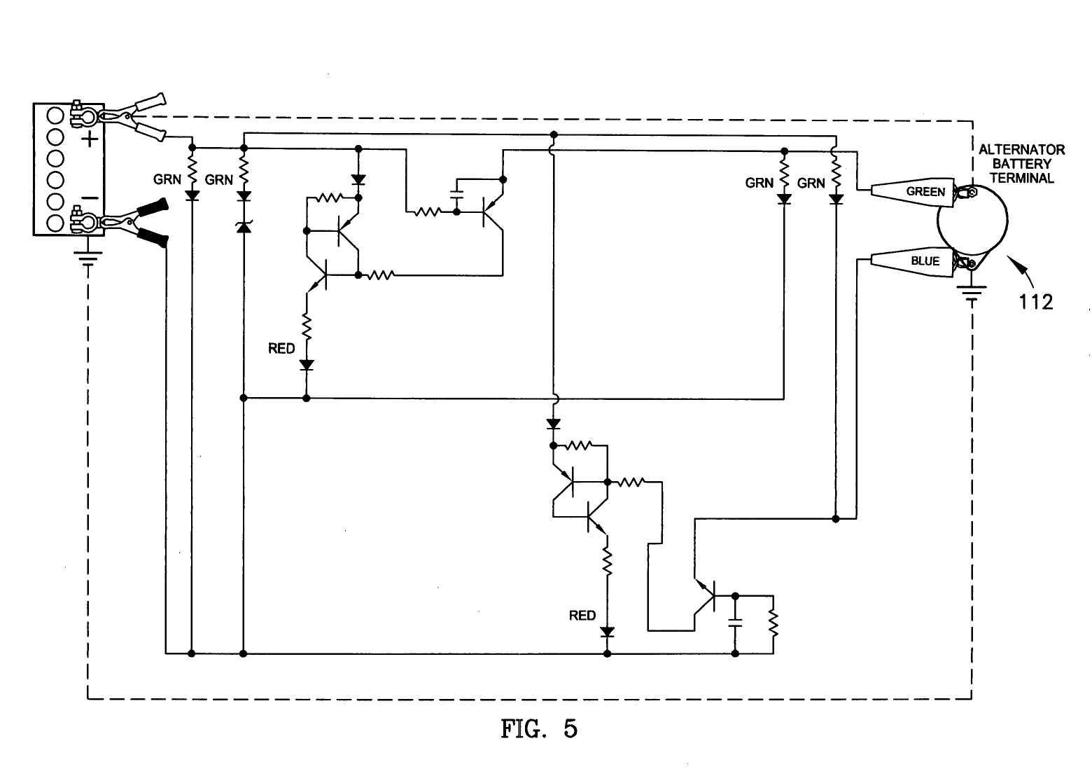

Although the present invention has been described with reference to the preferred embodiments illustrated in the drawings, it is noted that equivalents may be employed and substitutions made herein without departing from the contemplated scope of the present invention. As mentioned, the device is not limited to testing only the electric starter subsystem shown in FIG. 1, but is readily adaptable to test other electrical subsystems as well. Referring to FIG. 5, for example, a circuit schematic and connection diagram is shown for a preferred second embodiment of the device 110 adapted for testing a battery charging subsystem 112.

1. A circuit testing device for testing an electrical subsystem of a vehicle, the circuit testing device comprising:
a housing including a display and control panel for communicating a test result, wherein the display and control panel includes at least a pair of indicators for communicating the test result, with a first indicator of the pair of indicators communicating that the test result is satisfactory and a second indicator of the pair of indicators communicating that the test result is unsatisfactory;
at least three connectors, with each connector being adapted for connection to a particular point on the electrical subsystem; and
a testing circuitry adapted to receive one or more inputs via the connectors regarding the electrical subsystem, processing the input, and providing the test result to the display and control panel.

2. The circuit testing device as set forth in claim 1, wherein the connectors are each distinctly colored so as to facilitate proper identification and connection.

3. The circuit testing device as set forth in claim 1, wherein the second indicator of the pair of indicators also communicates the disconnection of at least one of the connectors.

4. The circuit testing device as set forth in claim 1, wherein the testing circuitry is adapted to latch the test result, and the display and control panel further includes a reset button adapted to clear the latched test result to permit another test.

5. The circuit testing device as set forth in claim 1, wherein the testing circuitry is adapted to determine a characteristic system voltage of the electrical subsystem.

6. The circuit testing device as set forth in claim 1, wherein the testing circuitry is adapted to delay for a pre-established time period before processing the input so as to allow the electrical subsystem to stabilize.

7. The circuit testing device as set forth in claim 1, wherein the pre-established time period is approximately one second.

8. The circuit testing device as set forth in claim 1, wherein the testing circuitry is adapted to determine whether an initial voltage level of the electrical subsystem is sufficient so that the test result will be accurate.

9. A circuit testing device for testing an electrical subsystem of a vehicle, the circuit testing device comprising:
a housing including a display and control panel for communicating a test result, wherein the display and control panel includes at least a pair of indicators for communicating the test result, with a first indicator of the pair of indicators communicating that the test result is satisfactory and a second indicator of the pair of indicators communicating that the test result is unsatisfactory;
at least three connectors, with each connector being adapted for connection to a particular point on the electrical subsystem, wherein the connectors are each distinctly colored so as to facilitate proper identification and connection; and
a testing circuitry adapted to receive one or more inputs via the connectors regarding the electrical subsystem, processing the input, and providing the test result to the display and control panel, wherein the testing circuitry is adapted to latch the test result,
wherein the display and control panel further includes a reset button adapted to clear the latched test result to permit another test.

10. The circuit testing device as set forth in claim 9, wherein the second indicator of the pair of indicators also communicates the disconnection of at least one of the connectors.

11. The circuit testing device as set forth in claim 9, wherein the testing circuitry is adapted to determine a characteristic system voltage of the electrical subsystem.

12. The circuit testing device as set forth in claim 9, wherein the testing circuitry is adapted to delay for a pre-established time period before processing the input so as to allow the electrical subsystem to stabilize.

13. The circuit testing device as set forth in claim 9, wherein the pre-established time period is approximately one second.

14. The circuit testing device as set forth in claim 9, wherein the testing circuitry is adapted to determine whether an initial voltage level of the electrical subsystem is sufficient so that the test result will be accurate.

15. A circuit testing device for testing an electrical subsystem of a vehicle, the circuit testing device comprising:
a housing including a display and control panel for communicating a test result, wherein the display and control panel includes at least a pair of LEDs for communicating the test result, with a first LED of the pair of LEDs communicating that the test result is satisfactory and a second LED of the pair of LEDs communicating that the test result is unsatisfactory;
at least three connectors, with each connector being adapted for connection to a particular point on the electrical subsystem, wherein the connectors are each distinctly colored so as to facilitate proper identification and connection; and
a testing circuitry adapted to
determine a characteristic system voltage of the electrical subsystem,
determine whether an initial voltage level of the electrical subsystem is sufficient so that the test result will be accurate,
delay for a pre-established time period so as to allow the electrical subsystem to stabilize,
receive one or more inputs via the connectors regarding the electrical subsystem, process the input, and provide the test result to the display and control panel, and
latch the test result,
wherein the display and control panel further includes a reset button adapted to clear the latched test result to permit another test, and wherein the second LED of the pair of LEDs also communicates the disconnection of at least one of the connectors.

16. A circuit testing device for testing an electric starter subsystem of a vehicle, the circuit testing device comprising:
a housing including a display and control panel for communicating a set of test results, wherein the display and control panel includes at least four pairs of LEDs for communicating the set of test results, with a first LED of each pair of LEDs communicating that a particular test result of the set of test results is satisfactory and a second LED of each pair of LEDs communicating that the particular test result is unsatisfactory;
at least four connectors, with each connector being adapted for connection to a particular point on the electrical subsystem, wherein the connectors are each distinctly colored so as to facilitate proper identification and connection; and
a testing circuitry adapted to
determine a characteristic system voltage of the electrical subsystem,
determine whether an initial voltage level of the electrical subsystem is sufficient so that the set of test results will be accurate,
delay for a pre-established time period so as to allow the electrical subsystem to stabilize,
receive one or more inputs via the connectors regarding the electrical subsystem, process the input, and provide the set of test results to the display and control panel, and
latch the set of test results,
wherein the display and control panel further includes a reset button adapted to clear the latched set of test results to permit another test.

17. The circuit testing device as set forth in claim 16, wherein the second LED of the pair of LEDs also communicates the disconnection of at least one of the connectors.
